(19) United States
(12) Patent Application Publication
(10) Pub. No.: US 2026/0075833 A1
(43) Pub. Date: Mar. 12, 2026

(54) FERROELECTRIC FIELD EFFECT TRANSISTOR HAVING VERTICAL STRUCTURE, SEMICONDUCTOR DEVICE INCLUDING FERROELECTRIC FIELD EFFECT TRANSISTOR, AND OPERATING METHOD OF SEMICONDUCTOR DEVICE

(71) Applicant: Samsung Electronics Co., Ltd., Suwon-si (KR)

(72) Inventors: Sijung YOO, Suwon-si (KR); Seunggeol NAM, Suwon-si (KR); Dukhyun CHOE, Suwon-si (KR)

(73) Assignee: Samsung Electronics Co., Ltd., Suwon-si (KR)

(21) Appl. No.: 19/172,960

(22) Filed: Apr. 8, 2025

(30) Foreign Application Priority Data
Sep. 9, 2024 (KR) 10-2024-0122580

(51) Int. Cl. H10B 51/30; G11C 11/22; H10B 51/10; H10B 51/20; H10B 51/40

(52) U.S. Cl. CPC H10B 51/30; G11C 11/223; G11C 11/2257; G11C 11/2273; H10B 51/10; H10B 51/20; H10B 51/40

(57) ABSTRACT

Provided are a ferroelectric field effect transistor having a vertical structure, a semiconductor device including the ferroelectric field effect transistor, a method of fabricating the semiconductor device, and an operating method of the semiconductor device. A ferroelectric field effect transistor includes a gate electrode extending in the first direction, a ferroelectric layer extending in the first direction on a side surface of the gate electrode, a channel layer extending in the first direction on a side surface of the ferroelectric layer, a first source/drain contact electrically connected to a lower surface of the channel layer, a second source/drain contact electrically connected to an upper surface of the channel layer, and a gate contact electrically connected to an upper surface of the gate electrode.

### CROSS-REFERENCE TO RELATED APPLICATION

This application is based on and claims priority under 35 U.S.C. § 119 to Korean Patent Application No. 10-2024-0122580, filed on Sep. 9, 2024, in the Korean Intellectual Property Office, the disclosure of which is incorporated by reference herein in its entirety.

### BACKGROUND

### 1. Field

The disclosure relates to a ferroelectric field effect transistor having a vertical structure, a semiconductor device including the ferroelectric field effect transistor, and an operating method of the semiconductor device.

### 2. Description of the Related Art

Ferroelectrics are materials that have ferroelectricity, which maintains spontaneous polarization by aligning internal electric dipole moments even when an electric field is no longer being applied (e.g., from an external electric field source). Even when a certain voltage is applied to a ferroelectric and the voltage is returned to 0 V, polarization remains semi-permanent in the ferroelectric. Research on applying these ferroelectric properties to logic devices or memory devices is ongoing. For example, in the case of a ferroelectric field effect transistor using a ferroelectric, the threshold voltage of the field effect transistor may vary depending on the direction and intensity of the polarization in the ferroelectric. Logic devices or memory devices may be implemented using threshold voltage variation characteristics of such ferroelectric field effect transistors.

### SUMMARY

Provided is a ferroelectric field effect transistor having a vertical structure.

Provided is a semiconductor device including a ferroelectric field effect transistor having a vertical structure.

Provided is a method of manufacturing a semiconductor device including a ferroelectric field effect transistor having a vertical structure.

Provided is an operating method of a semiconductor device including a ferroelectric field effect transistor having a vertical structure.

Additional aspects will be set forth in part in the description which follows and, in part, will be apparent from the description, or may be learned by practice of the presented embodiments of the disclosure.

According to an aspect of at least one embodiment, a semiconductor device includes a first layer bit line, a second layer bit line spaced apart from the first layer bit line in a first direction, a third layer bit line spaced apart from the second layer bit line in the first direction, and a plurality of ferroelectric field effect transistors including one or more ferroelectric field effect transistors between the first layer bit line and the second layer bit line and one or more ferroelectric field effect transistors between the second layer bit line and the third layer bit line, wherein each of the plurality of ferroelectric field effect transistors includes a gate electrode extending in the first direction, a ferroelectric layer extending in the first direction on a side surface of the gate electrode, a channel layer extending in the first direction on a side surface of the ferroelectric layer, a first source/drain contact electrically connected to a lower surface of the channel layer, a second source/drain contact electrically connected to an upper surface of the channel layer, and a gate contact electrically connected to an upper surface of the gate electrode, and wherein the first source/drain contact of each of the one or more ferroelectric field effect transistors between the first layer bit line and the second layer bit line is electrically connected to the first layer bit line, and the second source/drain contact of each of the one or more ferroelectric field effect transistors between the first layer bit line and the second layer bit line is electrically connected to the second layer bit line.

The first source/drain contact of each of the one or more ferroelectric field effect transistors between the second layer bit line and the third layer bit line may be electrically connected to the second layer bit line, and the second source/drain contact of each of the one or more ferroelectric field effect transistors between the second layer bit line and the third layer bit line may be electrically connected to the third layer bit line.

The second layer bit line may be configured as a common bit line between the one or more ferroelectric field effect transistors between the first layer bit line and the second layer bit line and the one or more ferroelectric field effect transistors between the second layer bit line and the third layer bit line.

The semiconductor device may further include a first layer word line spaced apart from the first layer bit line and the second layer bit line in the first direction such that the first layer word line is between the first layer bit line and the second layer bit line, and a second layer word line spaced apart from the second layer bit line and the third layer bit line in the first direction such that the second layer word line is between the second layer bit line and the third layer bit line, wherein the gate contact of each of the one or more of ferroelectric field effect transistors between the first layer bit line and the second layer bit line may be electrically connected to the first layer word line, and the gate contact of each of the one or more of ferroelectric field effect transistors between the second layer bit line and the third layer bit line may be electrically connected to the second layer word line.

Each of the first layer bit line, the second layer bit line, and the third layer bit line may include a plurality of bit lines extending in a second direction perpendicular to the first direction and spaced apart from each other in a third direction perpendicular to the first direction and the second direction, and each of the first layer word line and the second layer word line may include a plurality of word lines crossing the plurality of bit lines in a plan view.

The plurality of ferroelectric field effect transistors may be arranged in a hexagonal lattice form, and the plurality of word lines may obliquely cross the plurality of bit lines in the plan view.

The semiconductor device may further include a first row decoder configured to provide a control signal to the plurality of word lines of the first layer word line, a second row decoder configured to provide a control signal to the plurality of word lines of the second layer word line, a first column decoder electrically connected to the plurality of bit lines of the first layer bit line, a second column decoder electrically connected to the plurality of bit lines of the second layer bit line, a third column decoder electrically connected to the plurality of bit lines of the third layer bit line, and a sense amplifier electrically connected to the second column decoder and configured to amplify a signal output from the second column decoder.

The semiconductor device may be configured such that when the one or more ferroelectric field effect transistors between the first layer bit line and the second layer bit line are turned on, a driving voltage is applied to the first layer bit line, and a current flows from the first layer bit line to the second layer bit line, and when the one or more ferroelectric field effect transistors between the second layer bit line and the third layer bit line are turned on, a driving voltage is applied to the third layer bit line, and a current flows from the third layer bit line to the second layer bit line.

The semiconductor device may include a plurality of bit line layers, and each of the plurality of sense amplifiers may be only on bit lines of even-numbered bit line layers.

According to another aspect of at least one embodiment, an operating method of a semiconductor device including a plurality of first layer ferroelectric field effect transistors including at least one of ferroelectric field effect transistor between a first layer bit line and a second layer bit line; and a plurality of second layer ferroelectric field effect transistors between the second layer bit line and a third layer bit line, the operating method including applying a read voltage to a gate electrode of each of the plurality of first layer ferroelectric field effect transistors, applying a driving voltage to the first layer bit line such that a signal is output from the first layer bit line through the second layer bit line, applying a read voltage to a gate electrode of each of the plurality of second layer ferroelectric field effect transistors, applying a driving voltage to the third layer bit line such that a signal is output from the third layer bit line through the second layer bit line.

The method of operating the semiconductor device may further include amplifying the signal output from the second layer bit line.

Each of the first layer bit line, the second layer bit line, and the third layer bit line may include a plurality of bit lines, the outputting of the signal from the first layer bit line through the second layer bit line may include sequentially outputting a signal through the plurality of bit lines of the first layer bit line and the plurality of bit lines of the second layer bit line, and the outputting of the signal from the third layer bit line through the second layer bit line may include sequentially outputting a signal through the plurality of bit lines of the third layer bit line and the plurality of bit lines of the second layer bit line.

According to another aspect of at least one embodiment, a ferroelectric field effect transistor includes a gate electrode extending in a first direction, a ferroelectric layer extending in the first direction on a side surface of the gate electrode, a channel layer extending in the first direction on a side surface of the ferroelectric layer, a first source/drain contact electrically connected to a lower surface of the channel layer, a second source/drain contact electrically connected to an upper surface of the channel layer, and a gate contact electrically connected to an upper surface of the gate electrode.

The second source/drain contact may, in a plan view, overlap a portion of the upper surface of the channel layer and may be spaced apart from the gate electrode such that the second source/drain contact is not in electrical contact with the gate electrode, and the gate contact may overlap at least a portion of the upper surface of the gate electrode and may be spaced apart from the channel layer such that the gate contact is not in electrical contact with the channel layer.

A portion of the second source/drain contact may protrude outward from the channel layer on a plane in a second direction perpendicular to the first direction and in a third direction perpendicular to the first direction and the second direction, and a portion of the gate contact may protrude outward from the gate electrode on a plane in the second direction perpendicular to the first direction and in the third direction perpendicular to the first direction and the second direction to contact a portion of an upper surface of the ferroelectric layer.

In a plan view, a portion of the gate electrode between the second source/drain contact and the gate contact may be exposed without being covered by the gate contact.

The channel layer, the first source/drain contact, and the second source/drain contact may include one semiconductor material among a group IV semiconductor, a group III-V compound semiconductor, or a group II-VI compound semiconductor, the channel layer may be doped with a first conductivity type, and the first source/drain contact and the second source/drain contact may be doped with a second conductivity type electrically different to the first conductivity type.

The channel layer may include an oxide semiconductor material, and the first source/drain contact and the second source/drain contact may each include at least one of a conductive metal, a conductive metal oxide, or a conductive metal nitride.

The ferroelectric field effect transistor may further include an oxygen-deficient layer between the ferroelectric layer and the channel layer, the oxygen-deficient layer surrounding the side surface and a lower surface of the ferroelectric layer, and a diffusion barrier layer between the oxygen-deficient layer and the channel layer, the diffusion barrier layer surrounding a side surface and a lower surface of the oxygen-deficient layer, wherein the oxygen-deficient layer may include an oxide semiconductor material, and a concentration of oxygen vacancies in the oxygen-deficient layer may be greater than a concentration of oxygen vacancies in the channel layer, and the diffusion barrier layer may include at least one among silicon nitride (SiN), hafnium nitride (HfN), or aluminum nitride (AlN).

The ferroelectric field effect transistor may further include an intermediate electrode provided between the ferroelectric layer and the channel layer, the intermediate electrode surrounding at least a portion of the side surface and a lower surface of the ferroelectric layer, and an interlayer insulating layer surrounding a side surface and a lower surface of the intermediate electrode such that the interlayer insulating layer electrically insulates the intermediate electrode from the channel layer, wherein an upper surface of the intermediate electrode may be covered by at least one of the ferroelectric layer or the interlayer insulating layer such that the intermediate electrode is not in electrical contact with the gate contact.

According to another aspect of at least one embodiment, a method of manufacturing a semiconductor device may include forming a first layer bit line on a substrate, forming a first insulating layer on the substrate to cover the first layer bit line, forming a first source/drain contact being in electrical contact with the first layer bit line through the first insulating layer, forming a second insulating layer to cover an upper surface of the first insulating layer and an upper surface of the first source/drain contact, sequentially forming a channel layer to be in electrical contact with the first source/drain contact through the second insulating layer, a ferroelectric layer in the channel layer, and a gate electrode in the ferroelectric layer, forming a third insulating layer to cover the second insulating layer, the gate electrode, the ferroelectric layer, and the upper surface of the channel layer, forming a gate contact being in electrical contact with the gate electrode through the third insulating layer, forming a word line on the third insulating layer in electrical contact with the gate contact, forming a fourth insulating layer to cover the third insulating layer and the word line, forming a second source/drain contact in electrical contact with the channel layer, through the fourth insulating layer and the third insulating layer, and forming a second layer bit line on the fourth insulating layer and being in electrical contact with the second source/drain contact.

The forming of the channel layer, the ferroelectric layer, and the gate electrode may include partially etching the second insulating layer to form a hole penetrating the second insulating layer such that that the first source/drain contact is partially exposed, forming the channel layer along the inner wall and bottom of the hole, forming the ferroelectric layer on the surface of the channel layer, and forming the gate electrode on the surface of the ferroelectric layer.

The method of manufacturing a semiconductor device may further include forming the first insulating layer on the second layer bit line, forming the first source/drain contact, forming the second insulating layer, sequentially forming the channel layer, the ferroelectric layer, and the gate electrode, forming the third insulating layer, forming the gate contact, forming the word line, forming the fourth insulating layer, forming the second source/drain contact.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a vertical cross-sectional view schematically showing a structure of a ferroelectric field effect transistor according to at least one embodiment;

FIG. 2 is a horizontal cross-sectional view illustrating arrangement of a source/drain contact and a gate contact in the ferroelectric field effect transistor shown in FIG. 1;

FIG. 3 is a cross-sectional view schematically illustrating a structure of a semiconductor device according to at least one embodiment;

FIG. 4 shows the arrangement of bit lines and word lines connected to one ferroelectric field effect transistor of the semiconductor device shown in FIG. 3;

FIG. 5 shows a two-dimensional arrangement of a plurality of ferroelectric field effect transistors of the semiconductor device illustrated in FIG. 3;

FIG. 6 illustrates a circuit structure of the semiconductor device illustrated in FIG. 3;

FIGS. 7A and 7B illustrate a read operation of the semiconductor device illustrated in FIG. 6;

FIGS. 8A to 8V illustrate a process of manufacturing the semiconductor device illustrated in FIG. 3;

FIG. 9 is a vertical cross-sectional view schematically showing a structure of a ferroelectric field effect transistor according to another embodiment;

FIG. 10 is a vertical cross-sectional view schematically showing a structure of a ferroelectric field effect transistor according to another embodiment;

FIG. 11 is a graph showing a concentration distribution of oxygen vacancies in an oxygen-deficient layer and a channel layer of the ferroelectric field effect transistor illustrated in FIG. 10;

FIG. 12 is a vertical cross-sectional view schematically showing a structure of a ferroelectric field effect transistor according to another embodiment;

FIG. 13 is a vertical cross-sectional view schematically showing a structure of a ferroelectric field effect transistor according to another embodiment; and

FIG. 14 is a vertical cross-sectional view schematically showing a structure of a ferroelectric field effect transistor according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a ferroelectric field effect transistor having a vertical structure, a semiconductor device including the ferroelectric field effect transistor, a method of manufacturing the semiconductor device, and an operating method of the semiconductor device will be described in detail with reference to the accompanying drawings. In the following drawings, the same reference numerals refer to the same components, and the size of each component in the drawings may be exaggerated for clarity and convenience of description. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. In addition, the embodiments described below are merely examples and various modifications are possible from these embodiments.

Hereinafter, terms “upper” or “top” or “lower” or “bottom” may include not only those directly above/below/left/right in contact, but also those above/below/left/right without contact. For example, such directional terms, such as “above”, “below”, and/or similar directional terms, are intended to encompass different orientations of the device in use or operation in addition to the orientation depicted in the figures, and that the device may be otherwise oriented (rotated 90 degrees or at other orientations) and the spatially relative terms used herein interpreted accordingly. The singular expression includes plural expressions unless the context clearly implies otherwise. In addition, when a part “includes” a component, this means that it may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in an appropriate order and are not necessarily limited to the described order.

Further, the terms “unit”, “module” or the like mean a unit that processes at least one function or operation, which may be implemented in processing circuitry such as hardware or software or implemented in a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components (such as at least one of transistors, resistors, capacitors, etc.), and/or electronic circuits including said components.

The connection or connection members of lines between the components shown in the drawings exemplarily represent functional connection and/or physical or circuit connections, and may be replaceable or represented as various additional functional connections, physical connections, or circuit connections in an actual device.

The use of all examples or exemplary terms is merely for describing a technical idea in detail and the scope is not limited to the examples or exemplary terms unless limited by the claims.

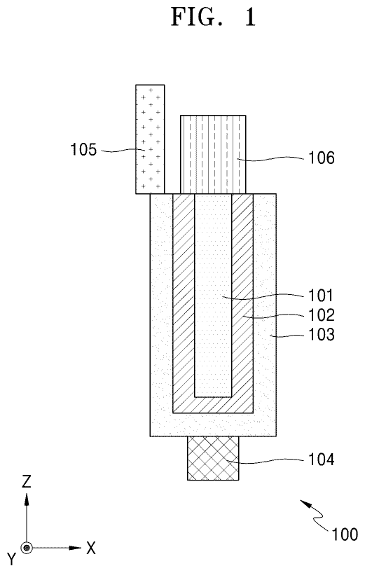

FIG. 1 is a vertical cross-sectional view schematically showing a structure of a ferroelectric field effect transistor according to at least one embodiment. Referring to FIG. 1, a ferroelectric field effect transistor 100 according to at least one embodiment includes a gate electrode 101, which extends in a first direction (e.g., a vertical direction or a Z direction); a ferroelectric layer 102, which surrounds a side surface and a lower surface of the gate electrode 101 and which extends in the first direction; a channel layer 103, which surrounds a side surface and a lower surface of the ferroelectric layer 102 and which extends in the first direction; a first source/drain contact 104, which is electrically connected to a lower surface of the channel layer 103; a second source/drain contact 105, which is electrically connected to an upper surface of the channel layer 103; and a gate contact 106, which is electrically connected to an upper surface of the gate electrode 101. Since the gate electrode 101, the ferroelectric layer 102, and the channel layer 103 extend in the vertical direction, the ferroelectric field effect transistor 100 shown in FIG. 1 may be considered to have a vertical structure.

The channel layer 103 may include at least one semiconductor material among an elemental semiconductor group (e.g., a group IV semiconductor such as silicon (Si), germanium (Ge), SiGe, etc.), a compound semiconductor group (e.g., a group III-V compound semiconductor such as GaAs, GaP, etc., and/or a group II-VI compound semiconductor), and/or an oxide semiconductor. When the channel layer 103 includes one of a semiconductor material other than an oxide semiconductor, for example, a group IV semiconductor, a group III-V compound semiconductor, or a group II-VI compound semiconductor described above, the channel layer 103 may be doped with a first conductivity type. For example, the channel layer 103 may be doped with an n-type dopant or a p-type dopant. In these cases, the first and second source/drain contacts 104 and 105 may be source/drain semiconductor regions. For example, the first and second source/drain contacts 104 and 105 may include at least one semiconductor material among a group IV semiconductor, a group III-V compound semiconductor, or a group II-VI compound semiconductor. The first and second source/drain contacts 104 and 105 may be doped with a second conductivity type that is electrically opposite to the channel layer 103. For example, if the channel layer 103 is doped with an n-type dopant, the first and second source/drain contacts 104 and 105 may be doped with a p-type dopant, and if the channel layer 103 is doped with a p-type dopant, the first and second source/drain contacts 104 and 105 may be doped with an n-type dopant.

When the channel layer 103 includes at least one oxide semiconductor material, for example, among indium-gallium-zinc oxide (IGZO), indium-zinc oxide (IZO), gallium-zinc oxide (GZO), zinc oxide (ZnO), zinc-tin oxide (ZTO), indium tungsten oxide (IWO), In₂O₃, Ga₂O₃, SnO₂, WO₃, etc., the channel layer 103 may not be doped. In these cases, the first and second source/drain contacts 104 and 105 may include a conductive material. For example, the first and second source/drain contacts 104 and 105 may include at least one material among conductive metals, conductive metal oxides, and conductive metal nitrides.

The ferroelectric layer 102 may include a ferroelectric material. Ferroelectrics are materials with ferroelectricity that maintain spontaneous polarization by aligning internal electric dipole moments without an electric field being applied from an external electric field source. The threshold voltage of the ferroelectric field effect transistor 100 according to the embodiment may change depending on a polarization direction of the ferroelectric layer 102, for example, a direction from the gate electrode 101 toward the channel layer 103 or vice versa.

The ferroelectric layer 102 may include, for example, a ferroelectric having a ferroelectric phase structure (e.g., at least one of a fluorite structure, a perovskite structure, and/or a wurtzite structure). The ferroelectric having a fluoride structure may include, for example, hafnium oxide (HfO₂). For example, the hafnium oxide may be doped with at least one element of zirconium (Zr), lanthanum (La), aluminum (Al), silicon (Si), yttrium (Y), and gadolinium (Gd). Alternatively, the ferroelectric layer 102 may include hafnium and zirconium in substantially the same element ratio (e.g., Hf_{0.5}Zr_{0.5}O₂), and additionally, at least one element among lanthanum (La), aluminum (Al), silicon (Si), yttrium (Y), and gadolinium (Gd) may be doped by a ratio of less than about 10 at %. In addition, the ferroelectric having a perovskite structure may include, for example, lead zirconate titanate (PZT). The ferroelectric having a wurtzite structure may include, for example, zinc oxide (ZnO) or aluminum nitride (AlN). The ferroelectric of such a wurtzite structure may be doped with, for example, at least one element of boron (B) and scandium (Sc). In at least some embodiments, the ferroelectric phase may be a dominant phase of the ferroelectric layer 102 such that the ferroelectric layer 102 has the ferroelectric property (e.g., compared to a comparative layer including a similar composition but different structure which would not exhibit the ferroelectric properties).

The ferroelectric layer 102 may further include an antiferroelectric material. For example, the antiferroelectric material may include zirconium oxide. For example, the zirconium oxide may be doped with at least one element of hafnium (Hf), lanthanum (La), aluminum (Al), silicon (Si), yttrium (Y), and/or gadolinium (Gd).

The gate electrode 101 may include a conductive material (e.g., a zero-band gap material) and/or the like. For example, the conductive material may one or more selected from the group consisting of metals, metal nitrides, metal carbides, polysilicon, and/or combinations thereof. For example, the metals may include aluminum (Al), tungsten (W), molybdenum (Mo), titanium (Ti), tantalum (Ta), etc., the metal nitrides may include titanium nitride (TiN), tantalum nitride (TaN) etc., and the metal carbides may include aluminum and/or silicon doped (or containing) metal carbides, for specific example, TiAlC, TaAlC, TiSiC, TaSiC, etc.

The gate contact 106 may include a conductive material such as at least one of conductive metals, conductive metal oxides, and conductive metal nitrides.

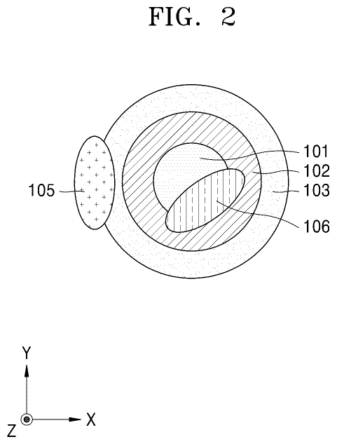

FIG. 2 is a horizontal cross-sectional view illustrating an arrangement of a second source/drain contact 105 and a gate contact 106 in the ferroelectric field effect transistor 100 shown in FIG. 1. Referring to FIG. 2, the channel layer 103 may be arranged at an outermost side, the ferroelectric layer 102 may be arranged inside the channel layer 103, and the gate electrode 101 may be arranged inside the ferroelectric layer 102. In other words, the ferroelectric layer 102 and the channel layer 103 may be sequentially arranged in a concentric shape in a manner surrounding the side surface of the gate electrode 101 having a cylindrical shape.

The second source/drain contact 105 may be arranged to be in contact with a portion of the upper surface of the channel layer 103. The second source/drain contact 105 is spaced apart from and not in contact with the gate electrode 101. In addition, a portion of the second source/drain contact 105 may protrude outward from the channel layer 103 on a plane (e.g., a horizontal plane) defined by the second direction (X direction) and the third direction (Y direction). The gate contact 106 may be arranged to be in contact with at least a portion of the upper surface of the gate electrode 101. A portion of the gate contact 106 may protrude outward from the gate electrode 101 on a plane (e.g., the horizontal plane) defined by the second direction (X direction) and the third direction (Y direction) to contact a portion of the upper surface of the ferroelectric layer 102, but is spaced apart from and does not contact the channel layer 103. In addition, the second source/drain contact 105 and the gate contact 106 may be electrically separated from each other.

In at least some embodiments, the gate contact 106 may be provided to cover the entire upper surface of the gate electrode 101. However, in at least some embodiments, the gate contact 106 may be provided on a first portion of the upper surface of the gate electrode 101 farthest from the second source/drain contact 105 in order to reduce the potential for short caused by an electrical contact between the second source/drain contact 105 and the gate contact 106. For example, when the second source/drain contact 105 is provided above the left region of the upper surface of the channel layer 103, the gate contact 106 may be provided above the right region of the upper surface of the gate electrode 101. Therefore, a second portion of the gate electrode 101 between the second source/drain contact 105 and the gate contact 106 may be exposed without being covered by the gate contact 106.

Since the ferroelectric field effect transistor 100 has a vertical structure in the first direction as described above, the ferroelectric field effect transistor 100 may have a relatively small area in a plan view. Therefore, the degree of integration of a semiconductor device (such as a memory) including the ferroelectric field effect transistor 100 may be improved. In addition, since the ferroelectric field effect transistor 100 according to the embodiment may be stacked relatively easily with multiple layers, a multi-layered semiconductor device may be manufactured relatively easily.

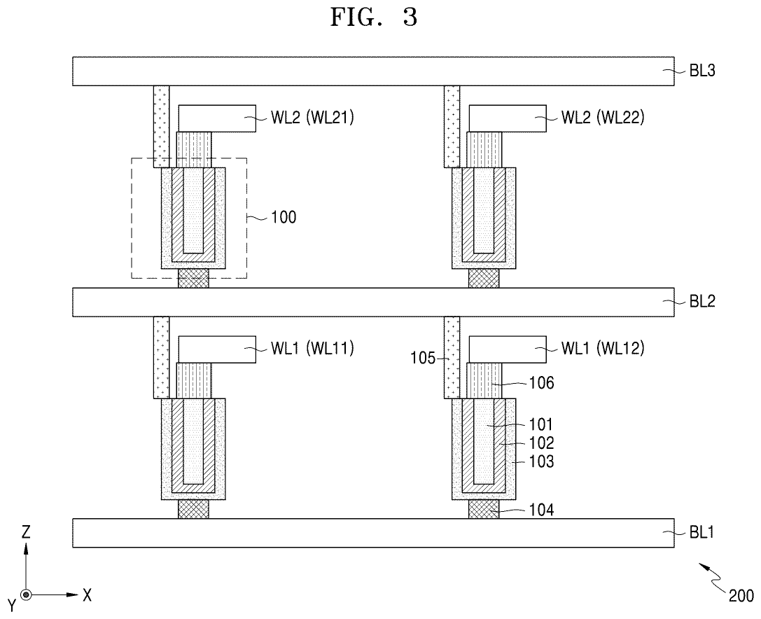

FIG. 3 is a cross-sectional view schematically illustrating a structure of a semiconductor device according to at least one embodiment. Referring to FIG. 3, a semiconductor device 200 may include a plurality of ferroelectric field effect transistors 100, a plurality of bit lines, and a plurality of word lines, which are stacked in a plurality of layers.

For example, the plurality of bit lines of the semiconductor device 200 may include a plurality of bit lines (e.g., a first layer bit line BL1, a second layer bit line BL2 arranged to be spaced apart from the first layer bit line BL1 by a predetermined interval in the first direction, and a third layer bit line BL3 arranged to be spaced apart from the second layer bit line BL2 by a predetermined interval in the first direction). The first layer bit line BL1, the second layer bit line BL2, and the third layer bit line BL3 may extend in the second (e.g., X) direction. Although only three layers of the bit lines are illustrated in FIG. 3 for convenience, the bit lines may include more than three layers.

A plurality of ferroelectric field effect transistors 100 may be two-dimensionally arranged between the first layer bit line BL1 and the second layer bit line BL2 in the second direction and the third direction. In addition, a plurality of ferroelectric field effect transistors 100 may be two-dimensionally arranged between the second layer bit line BL2 and the third layer bit line BL3 in the second (e.g., X) and third (e.g., Y) directions. For convenience, only two ferroelectric field effect transistors 100 arranged in the second direction in each layer are illustrated in FIG. 3, but a larger number of ferroelectric field effect transistors 100 may be provided in each layer.

The first source/drain contact 104 of each of the plurality of ferroelectric field effect transistors 100 provided in the first layer, that is, between the first layer bit line BL1 and the second layer bit line BL2, may be electrically connected to the first layer bit line BL1. For example, the first source/drain contact 104 of each of the plurality of ferroelectric field effect transistors 100 provided in the first layer may be in direct contact with the first layer bit line BL1. The second source/drain contact 105 of each of the plurality of ferroelectric field effect transistors 100 provided in the first layer may be electrically connected to the second layer bit line BL2. For example, the second source/drain contact 105 of each of the plurality of ferroelectric field effect transistors 100 provided in the first layer may be in direct contact with the second layer bit line BL2. In addition, the first source/drain contact 104 of each of the plurality of ferroelectric field effect transistors 100 provided in the second layer, e.g., between the second layer bit line BL2 and the third layer bit line BL3, may be electrically connected to the second layer bit line BL2, and the second source/drain contact 105 of each of the plurality of ferroelectric field effect transistors 100 provided in the second layer may be electrically connected to the third layer bit line BL2.

A bit line between two adjacent layers in which the ferroelectric field effect transistors 100 are provided may be referred to as a common bit line. For example, the second layer bit line BL2 may be a common bit line between the plurality of ferroelectric field effect transistors 100 provided in the first layer and the plurality of ferroelectric field effect transistors 100 provided in the second layer. To this end, the second source/drain contact 105 of each of the plurality of ferroelectric field effect transistors 100 provided in the first layer and the first source/drain contact 104 of each of the plurality of ferroelectric field effect transistors 100 provided in the second layer may be electrically connected to the second layer bit line BL2. If a plurality of ferroelectric field effect transistors 100 are further provided in the third layer, the third layer bit line BL2 may be a common bit line between the plurality of ferroelectric field effect transistors 100 provided in the second layer and the plurality of ferroelectric field effect transistors 100 provided in the third layer.

In addition, the plurality of word lines of the semiconductor device 200 may include a plurality of word lines (e.g., a first layer word line WL1 and a second layer word line WL2) arranged to be spaced apart from the first layer word line by a predetermined interval in the first (e.g., X) direction. Although only two layers of the word lines are illustrated in FIG. 3 for convenience, the word lines may include more than two layers. In addition, each of the first layer word line WL1 and the second layer word line WL2 may include a plurality of word lines arranged on a horizontal plane in the second direction and the third direction. For example, the first layer word line WL1 may include a first layer first word line WL11 and a first layer second word line WL12, and the second layer word line WL2 may include a second layer first word line WL21 and a second layer second word line WL22. Although only two word lines are illustrated in one word line layer for convenience in FIG. 3, a large number of word lines may be provided in each word line layer.

The first layer word line WL1 and the second layer word line WL2 may be provided at different heights from the first layer bit line BL1, the second layer bit line BL2, and the third layer bit line BL3. For example, the first layer word line WL1 may be spaced apart from the first layer bit line BL1 and the second layer bit line BL2 in the first (e.g., Z) direction between the first layer bit line BL1 and the second layer bit line BL2. The second layer word line WL2 may be spaced apart from the second layer bit line BL2 and the third layer bit line BL3 in the first direction between the second layer bit line BL2 and the third layer bit line BL3.

The gate contact 106 of each of the plurality of ferroelectric field effect transistors 100 provided in the first layer may be electrically connected to the first layer word line WL1. For example, the gate contact 106 of each of the plurality of ferroelectric field effect transistors 100 provided in the first layer may be in direct contact with one corresponding word line of the first layer first word line WL11 and the first layer second word line WL12. In addition, the gate contact 106 of each of the plurality of ferroelectric field effect transistors 100 provided on the second layer may be electrically connected to the second layer word line WL2. For example, the gate contact 106 of each of the plurality of ferroelectric field effect transistors 100 provided in the second layer may be in direct contact with one corresponding word line of the second layer first word line WL21 and the second layer second word line WL22. In this way, each of the plurality of word lines may be electrically connected to the gate electrode 101 of each of the ferroelectric field effect transistors 100 through the gate contact 106.

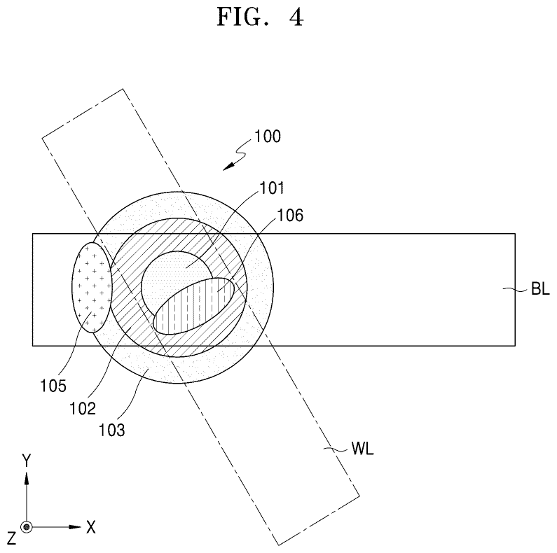

FIG. 4 shows the arrangement of bit lines and word lines connected to one ferroelectric field effect transistor 100 of the semiconductor device 200 shown in FIG. 3. Referring to FIG. 4, the bit line BL may be in electrical contact with the second source/drain contact 105 of the ferroelectric field effect transistor 100 and may extend in the (e.g., X) second direction. In other words, the length of the bit line BL in the second (e.g., X) direction may be much greater than the width in the third (e.g., Y) direction. The horizontal cross-sectional shape of the second source/drain contact 105 may have an elliptical or rectangular shape elongated in the third direction to increase the contact area with the bit line BL, but is not limited thereto.

The word line WL may be in electrical contact with the gate contact 106 of the ferroelectric field effect transistor 100 and may extend in a direction between the second direction and the third direction. Therefore, the word line WL may obliquely cross the bit line BL in a direction between the second direction and the third direction. The horizontal cross-sectional shape of the gate contact 106 may have a long elliptical or rectangular shape in the width direction of the word line WL perpendicular to the extending direction of the word line WL to increase the contact area with the word line WL, but is not limited thereto.

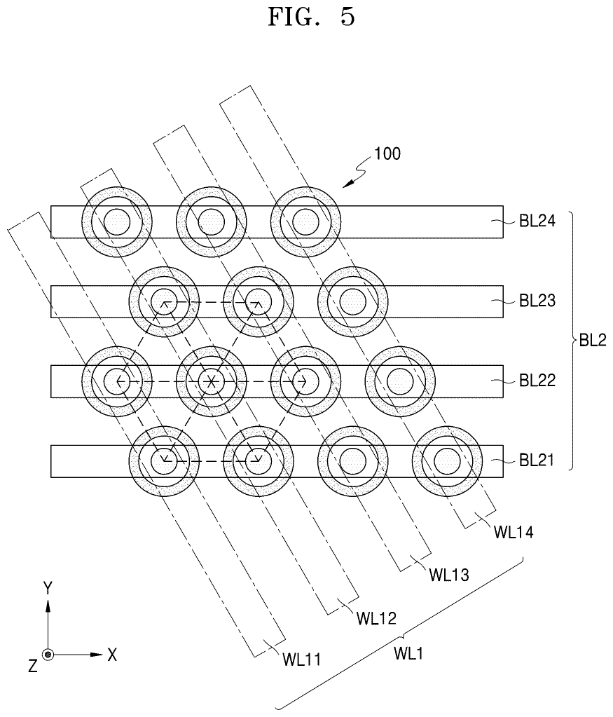

FIG. 5 shows a two-dimensional arrangement of a plurality of ferroelectric field effect transistors 100 of the semiconductor device 200 illustrated in FIG. 3. Referring to FIG. 5, the plurality of ferroelectric field effect transistors 100 arranged along one layer may be two-dimensionally arranged. For example, the plurality of ferroelectric field effect transistors 100 may be arranged in a hexagonal lattice shape in a plan (or overhead) view. Thereby, the number of ferroelectric field effect transistors 100 arranged in a unit area may be increased.

In one layer, a plurality of bit lines may be arranged to be spaced apart from each other in the third direction. For example, the second layer bit line BL2 may include a second layer first bit line BL21, a second layer second bit line BL21, a second layer third bit line BL23, and a second layer fourth bit line BL24, which are arranged to be spaced apart from each other in the third direction. Each of the second layer first bit line BL21, the second layer second bit line BL21, the second layer third bit line BL23, and the second layer fourth bit line BL24 may extend in the second direction to be electrically connected to the second source/drain contact 105 of each of the plurality of ferroelectric field effect transistors 100 arranged in the second direction within the first layer.

The first layer word line WL1 may include a first layer first word line WL11, a first layer second word line WL12, a first layer third word line WL13, and a first layer fourth word line WL14, which extend in a column direction between the second direction and the third direction. Each of the first layer first word line WL11, the first layer second word line WL12, the first layer third word line WL13, and the first layer fourth word line WL14 may be electrically connected to the gate contact 106 of each of the plurality of ferroelectric field effect transistors 100 arranged along one line inclined in the first layer. In this case, each of the first layer first word line WL11, the first layer second word line WL12, the first layer third word line WL13, and the first layer fourth word line WL14 may obliquely cross each of the second layer first bit line BL21, the second layer second bit line BL22, the second layer third bit line BL23, and the second layer fourth bit line BL24 at an inclined direction, for example, at an angle of about 60 degrees.

However, the two-dimensional arrangement of the plurality of ferroelectric field effect transistors 100 is not limited to the hexagonal lattice shape, and other types of arrangements are possible. For example, the plurality of ferroelectric field effect transistors 100 may be two-dimensionally arranged in a rectangular lattice shape. In this case, each of the first layer first word line WL11, the first layer second word line WL12, the first layer third word line WL13, and the first layer fourth word line WL14 may cross each of the second layer first bit line BL21, the second layer second bit line BL22, the second layer third bit line BL23, and the second layer fourth bit line BL24 at an inclined direction, for example, at an angle of about 90 degrees.

The semiconductor device 200 described above may be, for example, a memory device. In this case, one ferroelectric field effect transistor 100 may form one memory cell. According to at least one embodiment, in the semiconductor device 200 including the ferroelectric field effect transistor 100, since each unit memory cell does not include a capacitor, the area of one unit memory cell of the semiconductor device 200 may be reduced. In addition, since the ferroelectric field effect transistor 100 has a vertical structure, the area of the unit memory cell of the semiconductor device 200 may be further reduced. In addition, since unit memory cells may be stacked in a plurality of layers, the degree of integration of the semiconductor device 200 may be further increased.

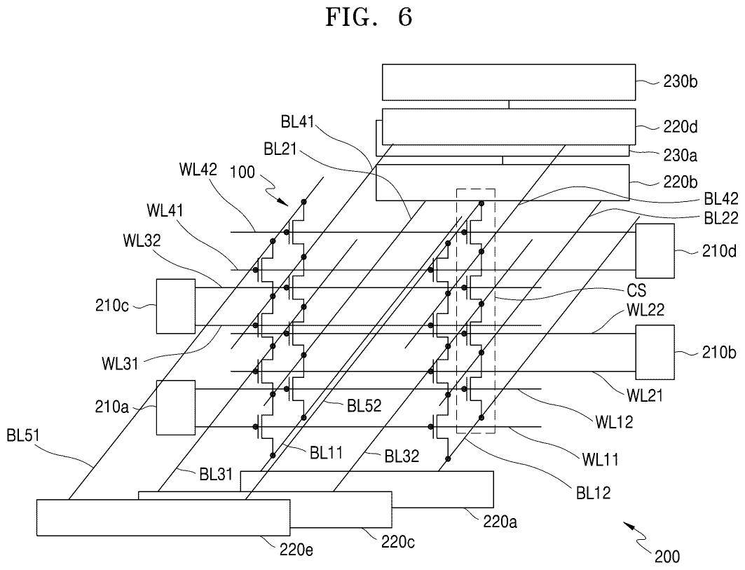

FIG. 6 illustrates a circuit structure of the semiconductor device 200 illustrated in FIG. 3. Referring to FIG. 6, a semiconductor device 200 may include a plurality of memory cell strings CS, a plurality of word lines, and a plurality of bit lines. The plurality of memory cell strings CS may be two-dimensionally arranged along a plurality of rows and a plurality of columns. Although FIG. 6 illustrates the plurality of memory cell strings CS arranged along two rows and two columns, this is merely an example and embodiments are not limited thereto. Each of the plurality of memory cell strings CS may include a plurality of ferroelectric field effect transistors 100 stacked in a plurality of layers in a first direction. The plurality of ferroelectric field effect transistors 100 may be connected in series to each other in each memory cell string CS. Although FIG. 6 illustrates that four ferroelectric field effect transistors 100 are stacked in each memory cell string CS, this is merely an example and embodiments are not limited thereto.

Among the plurality of word lines, a first layer first word line WL11 may be electrically connected to a gate contact 106 of each of the plurality of ferroelectric field effect transistors 100 arranged along a first row within the first layer, and a first layer second word line WL12 may be electrically connected to a gate contact 106 of each of the plurality of ferroelectric field effect transistors 100 arranged along a second row within the first layer. Likewise, a second layer first word line WL21 and a second layer second word line WL22 may be electrically connected to the gate contacts 106 of each of the plurality of ferroelectric field effect transistors 100 arranged along corresponding rows within the second layer, a third layer first word line WL31 and a third layer second word line WL32 may be electrically connected to the gate contacts 106 of each of the plurality of ferroelectric field effect transistors 100 arranged along corresponding rows within the third layer, and a fourth layer first word line WL41 and a fourth layer second word line WL42 may be electrically connected to the gate contacts 106 of each of the plurality of ferroelectric field effect transistors 100 arranged along corresponding rows within the fourth layer. Accordingly, the number of layers of the plurality of word lines may be the same as the number of layers in which the plurality of ferroelectric field effect transistors 100 are stacked.

Among the plurality of bit lines, a first layer first bit line BL11 may be electrically connected to the first source/drain contact 104 of each of the plurality of ferroelectric field effect transistors 100 arranged along the first column in the first layer, and a first layer second bit line BL12 may be electrically connected to the first source/drain contact 104 of each of the plurality of ferroelectric field effect transistors 100 arranged along the second column in the first layer.

The second layer first bit line BL21 may be electrically connected to the second source/drain contact 105 of each of the plurality of ferroelectric field effect transistors 100 arranged along the first column in the first layer and the first source/drain contact 104 of each of the plurality of ferroelectric field effect transistors 100 arranged along the first column in the second layer. The second layer second bit line BL22 may be electrically connected to the second source/drain contact 105 of each of the plurality of ferroelectric field effect transistors 100 arranged along the second column in the first layer and the first source/drain contact 104 of each of the plurality of ferroelectric field effect transistors 100 arranged along the second column row in the second layer. Accordingly, the second layer first bit line BL21 and the second layer second bit line BL22 may be common bit lines for the plurality of ferroelectric field effect transistors 100 arranged in the first layer and the second layer. Likewise, a third layer first bit line BL31 and a third layer second bit line BL32 may be common bit lines for the plurality of ferroelectric field effect transistors 100 arranged in the second layer and the third layer, and a fourth layer first bit line BL41 and a fourth layer second bit line BL42 may be common bit lines for the plurality of ferroelectric field effect transistors 100 arranged in the third layer and the fourth layer.

A fifth layer first bit line BL51 may be electrically connected to the second source/drain contacts 105 of each of the plurality of ferroelectric field effect transistors 100 arranged along the first column of the fourth layer, and a fifth layer second bit line BL52 may be electrically connected to the second source/drain contacts 105 of each of the plurality of ferroelectric field effect transistors 100 arranged along the second column in the fourth layer. Therefore, the number of layers of a plurality of bit lines may be greater by one than the number of layers in which a plurality of ferroelectric field effect transistors 100 are stacked. For example, when the plurality of ferroelectric field effect transistors 100 are stacked in N layers in the semiconductor device 200, the number of layers of the plurality of bit lines may be N+1. Here, N is a positive integer.

In addition, the semiconductor device 200 may further include a plurality of row decoders that provide control signals for read/write operations of the plurality of ferroelectric field effect transistors 100 to the plurality of word lines, a plurality of column decoders that output information recorded in the plurality of ferroelectric field effect transistors 100 through the plurality of bit lines, and a plurality of sense amplifiers that amplify output signals.

The plurality of row decoders may include a first row decoder 210a, a second row decoder 210b, a third row decoder 210c, and a fourth row decoder 210d. The first row decoder 210a may be configured to provide control signals to the first layer first word line WL11 and the first layer second word line WL12, the second row decoder 210b may be configured to provide control signals to the second layer first word line WL21 and the second layer second word line WL22, the third row decoder 210c may be configured to provide control signals to the third layer first word line WL31 and the third layer second word line WL32, and the fourth row decoder 210d may be configured to provide control signals to the fourth layer first word line WL41 and the fourth layer second word line WL42.

In addition, the plurality of column decoders may include a first column decoder 220a electrically connected to the first layer first bit line BL11 and the second layer second bit line BL12, a second column decoder 220b electrically connected to the second layer first bit line BL21 and the second layer second bit line BL22, a third column decoder 220c electrically connected to the third layer first bit line BL31 and the third layer second bit line BL32, a fourth column decoder 220d electrically connected to the fourth layer first bit line BL41 and the fourth layer second bit line BL42, and a fifth column decoder 220e electrically connected to the fifth layer first bit line BL51 and the fifth layer second bit line BL52.

The plurality of sense amplifiers may include a first sense amplifier 230a electrically connected to the second column decoder 220b to amplify a signal output from the second column decoder 220b and a second sense amplifier 230b electrically connected to the fourth column decoder 220d to amplify a signal output from the fourth column decoder 220d, etc. However, this is only an example, and the plurality of sense amplifiers may be provided to amplify signals output from even-numbered bit layers and/or common bit layers.

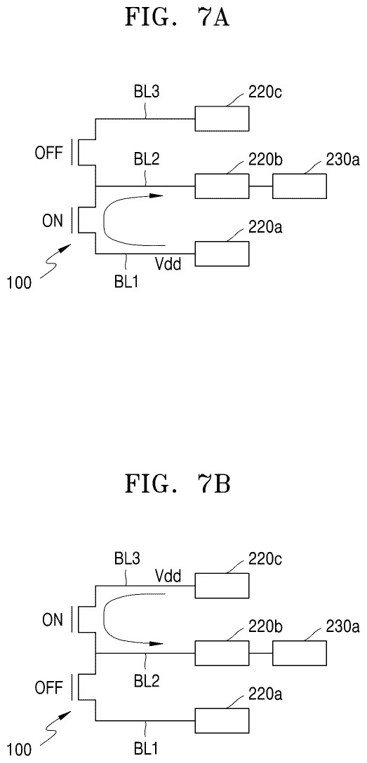

FIGS. 7A and 7B illustrate a read operation of the semiconductor device 200 illustrated in FIG. 6. In FIGS. 7A and 7B, only read operations of two layers of ferroelectric field effect transistors 100 are described for convenience.

First, referring to FIG. 7A, the first row decoder 210a (see FIG. 6) may apply a read voltage to the gate electrode 101 (see FIG. 3) of the ferroelectric field effect transistor 100 of the first layer through a word line. A voltage may not be applied to the gate electrode 101 of the ferroelectric field effect transistor 100 of the remaining layer. When the threshold voltage of the ferroelectric field effect transistor 100 of the first layer is less than the read voltage, that is, when the digital information recorded in the ferroelectric field effect transistor 100 is “1”, the ferroelectric field effect transistor 100 of the first layer may be turned on. The first column decoder 220a may apply a driving voltage Vdd to the first layer bit line BL1. The third column decoder 220c may make the third layer bit line BL3 floating. Then, a current may flow from the first layer bit line BL1 to the second layer bit line BL2 and output a signal through the second layer bit line BL2. The first sense amplifier 230a may amplify a current signal output from the second layer bit line BL2.

Although FIG. 7A illustrates the first layer bit line BL1, the second layer bit line BL2, and the third layer bit line BL3 as a representative layer for convenience, as shown in FIG. 6, each of the first layer bit line BL1, the second layer bit line BL2, and the third layer bit line BL3 may include a plurality of bit lines arranged along a plurality of columns in one layer. In addition, only one ferroelectric field effect transistor 100 in one layer is representatively illustrated in FIG. 7A, but as illustrated in FIG. 6, a plurality of word lines and a ferroelectric field effect transistors 100 may be arranged along a plurality of rows in one layer. Therefore, in practice, signals may be sequentially output through a plurality of bit lines of the first layer bit line BL1 and a plurality of bit lines of the second layer bit line BL2 while a read voltage is applied to one word line within one layer. When signals are completely output from all columns for one word line, signals may be sequentially output to a plurality of columns by applying a read voltage to the next word line. In this way, when read operations for all rows in the first layer are completed, read operations may be performed on the second layer.

Referring to FIG. 7B, the second row decoder 210b may apply a read voltage to the gate electrode 101 of the ferroelectric field effect transistor 100 of the second layer through a word line. A voltage may not be applied to the gate electrode 101 of the ferroelectric field effect transistor 100 of the remaining layer. When the digital information recorded in the ferroelectric field effect transistor 100 of the second layer is “1”, the ferroelectric field effect transistor 100 of the second layer may be turned on. The third column decoder 220c may apply a driving voltage Vdd to the third layer bit line BL3. The first column decoder 220a may make the first layer bit line BL1 floating. Then, a current may flow from the third layer bit line BL3 to the second layer bit line BL2 and output a signal through the second layer bit line BL2. The first sense amplifier 230a may amplify a current signal output from the second layer bit line BL2.

Therefore, since one sense amplifier may amplify the output of each of the ferroelectric field effect transistors 100 in two layers, the semiconductor device 200 may include one sense amplifier for every two layers. For example, the sense amplifier may be provided only in the bit line of an even-numbered layer. Therefore, when the number of bit line layers is even, the semiconductor device 200 may include N/2 sense amplifiers for N bit line layers. When the number of layers is odd, the semiconductor device 200 may include (N−1)/2 sense amplifiers. Therefore, the area occupied by the sense amplifiers in the entire area of the semiconductor device 200 may be relatively reduced and the area occupied by the unit memory cells may be relatively increased.

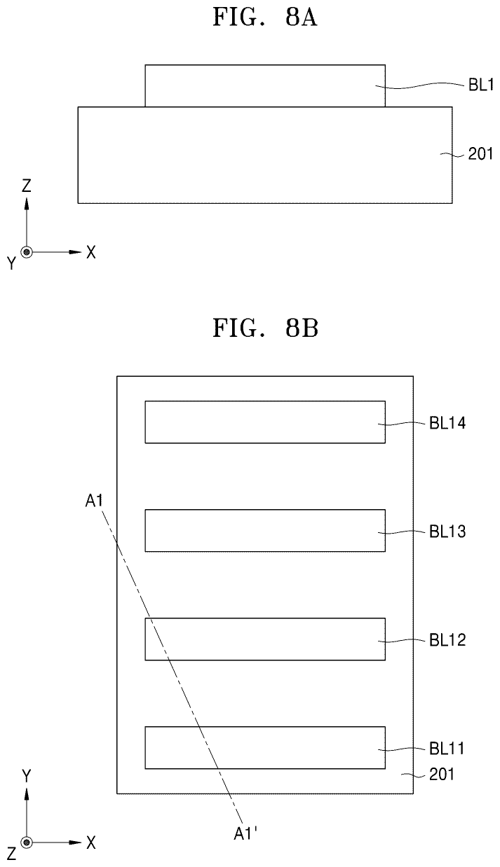

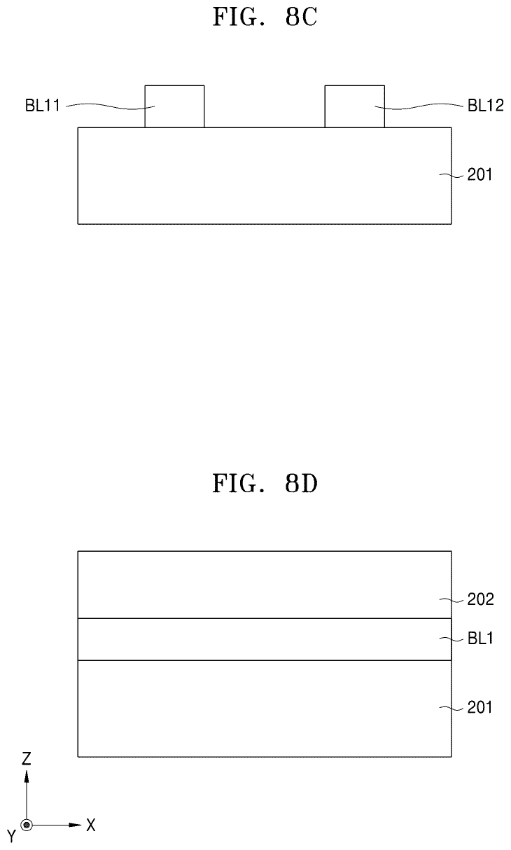

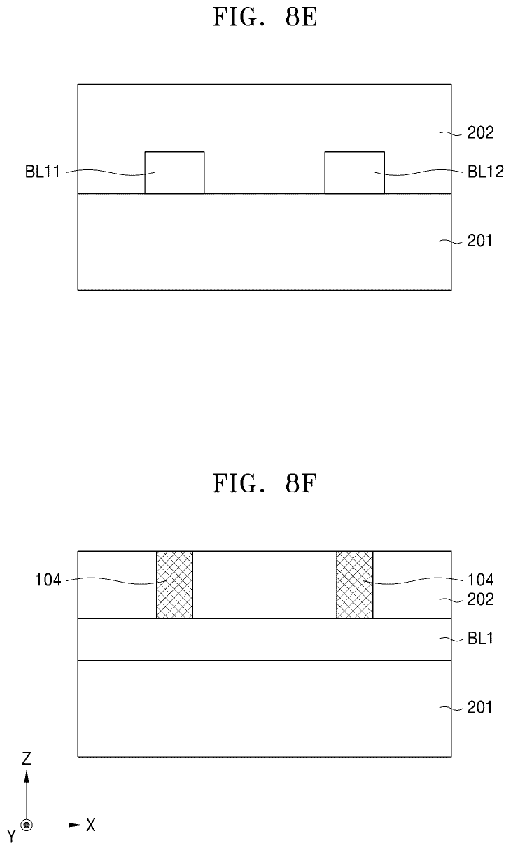

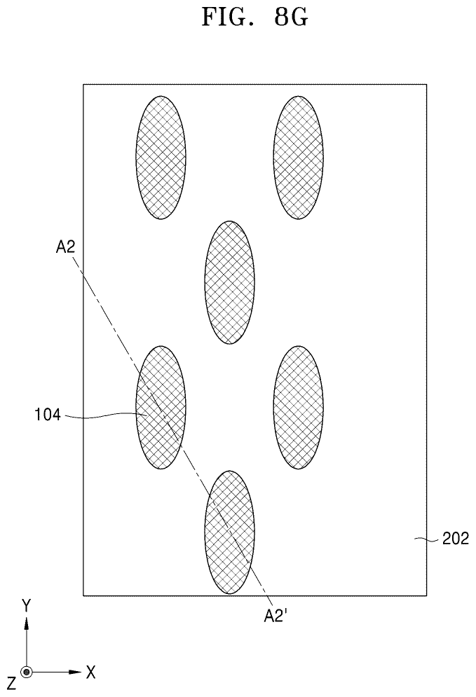

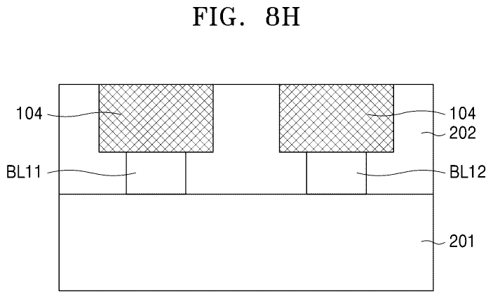

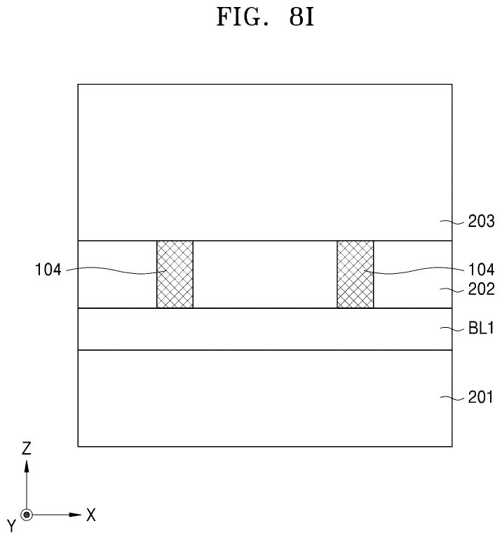

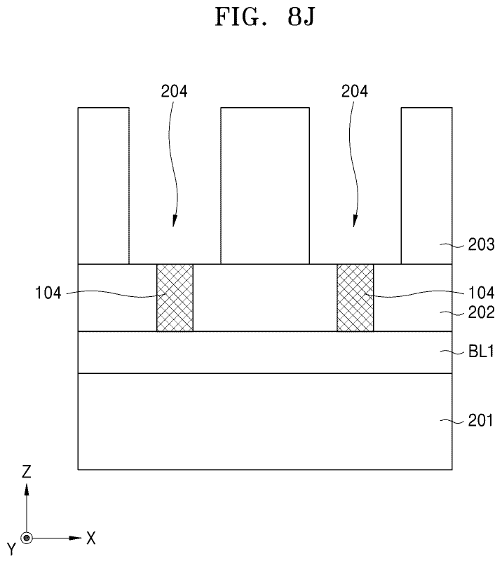

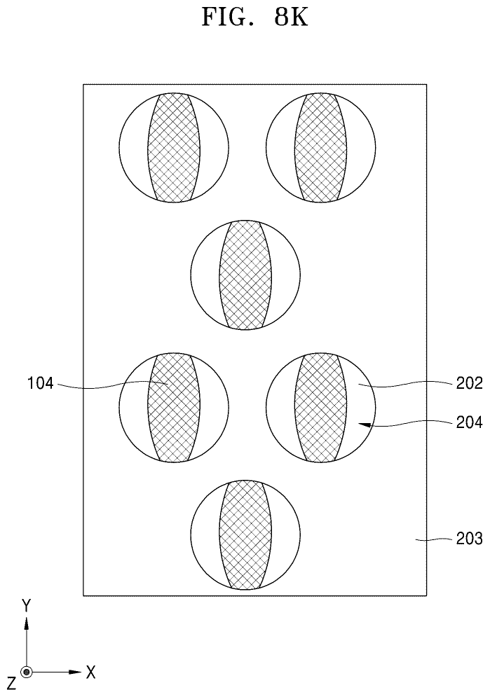

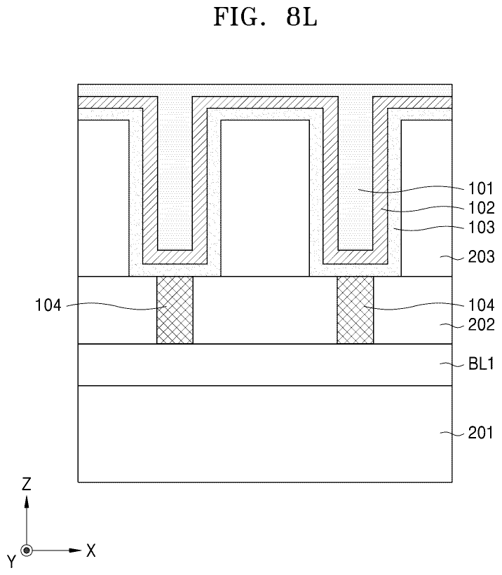

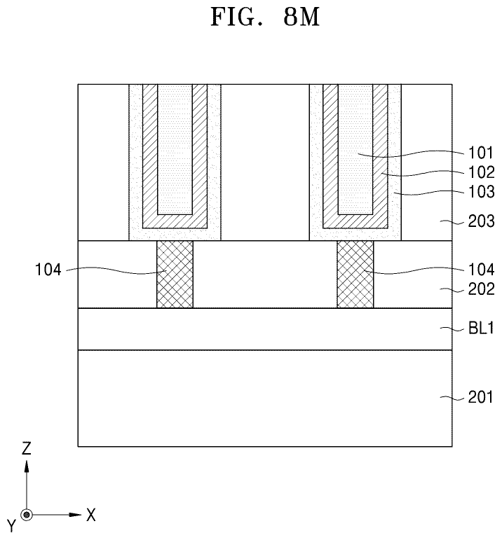

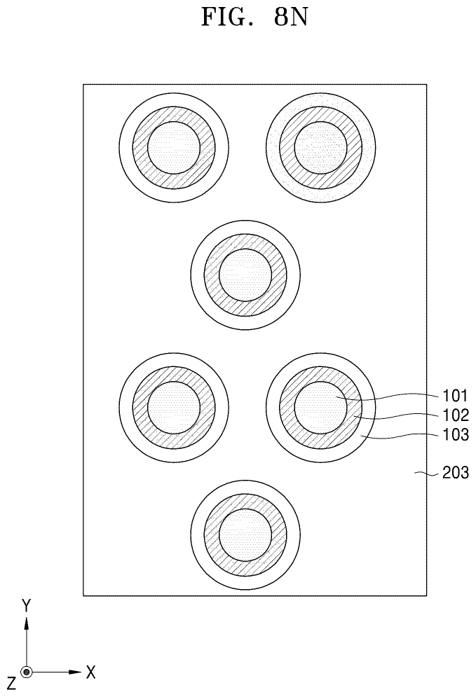

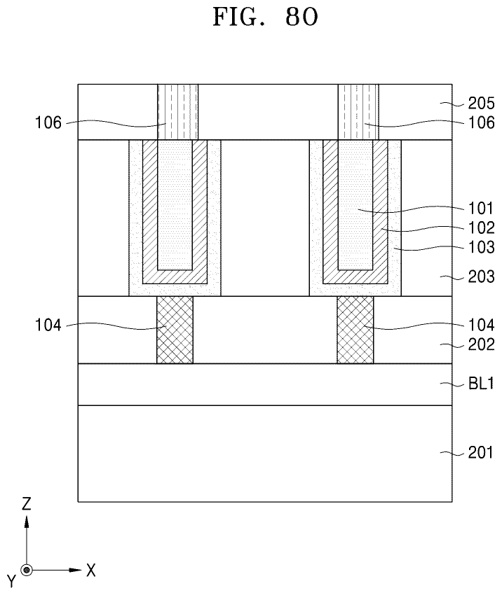

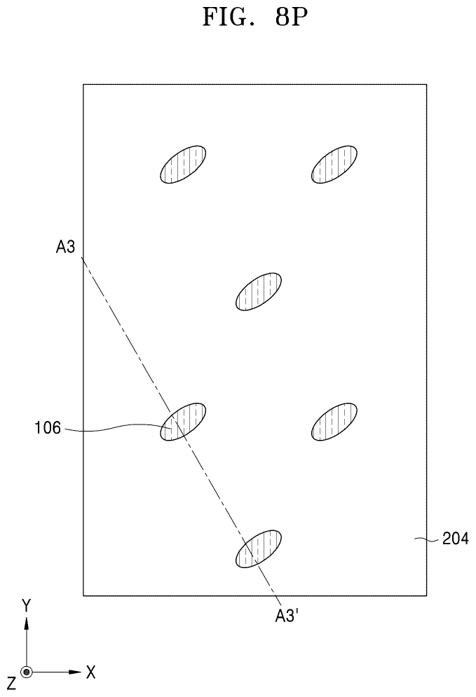

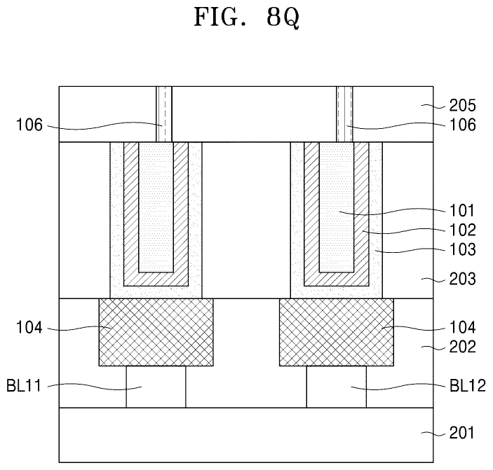

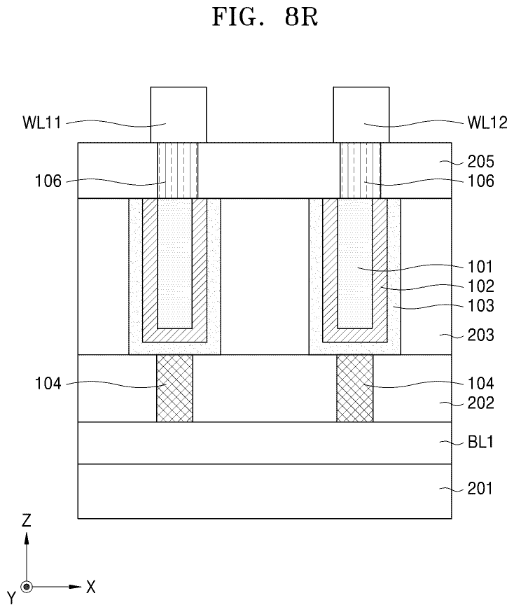

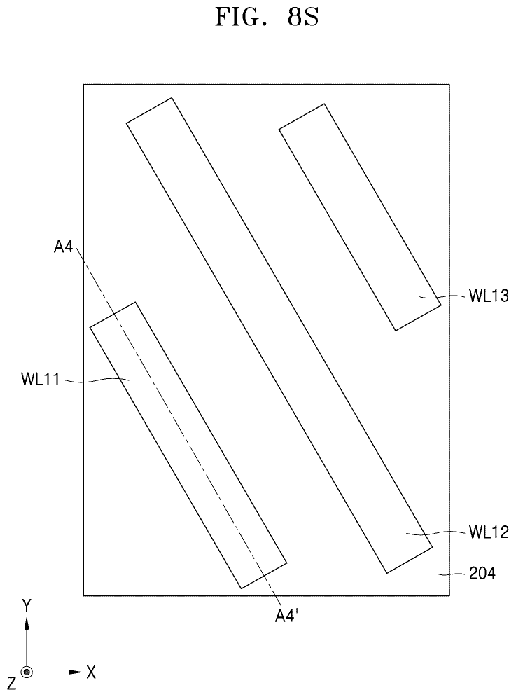

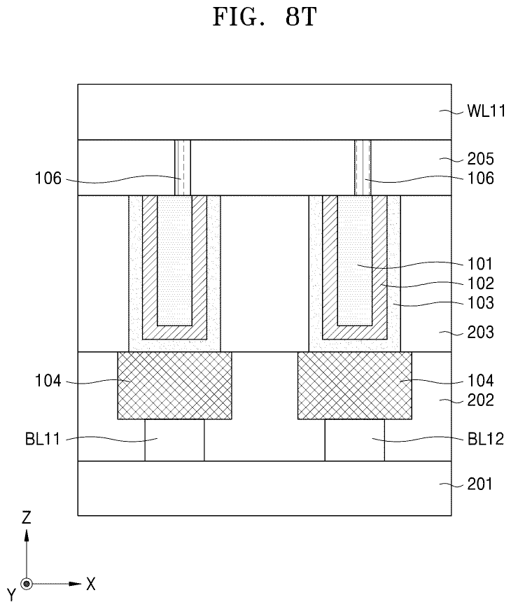

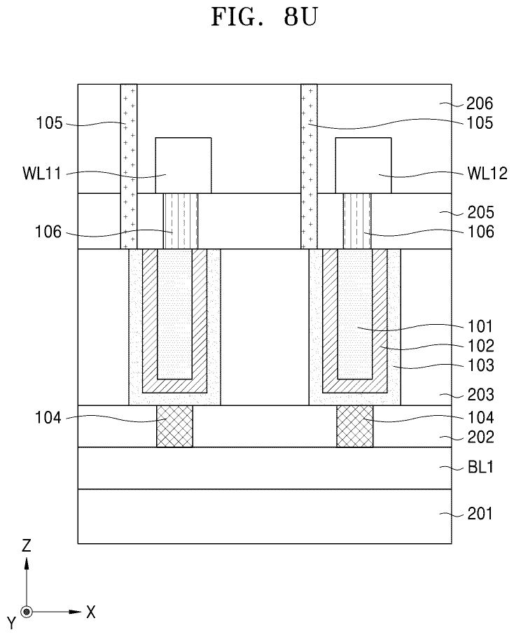

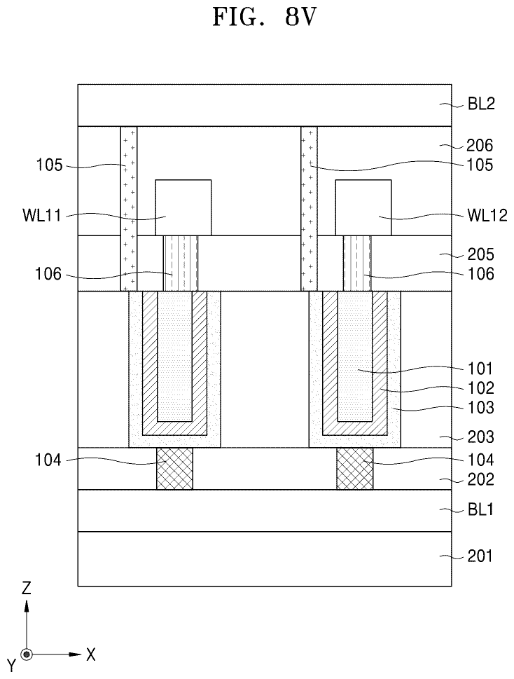

FIGS. 8A to 8V illustrate a process of manufacturing the semiconductor device 200 illustrated in FIG. 3.

Referring to FIG. 8A, a first layer bit line BL1 extending in a second direction (X direction) may be first formed on a substrate 201. The substrate 201 may be a semiconductor substrate. Alternatively, the substrate 201 may be a driving substrate including a driving circuit for driving the semiconductor device 200. For example, after depositing a conductive metal layer on the upper surface of the substrate 201, the conductive metal layer may be patterned to form the first layer bit line BL1.

FIG. 8B is a plan view after forming the first layer bit line BL1, and FIG. 8C is a cross-sectional view taken along line A1-A1′ shown in FIG. 8B. Referring to FIGS. 8B and 8C, the first layer bit line BL1 may include a plurality of bit lines extending in the second direction. For example, the plurality of bit lines may include a first layer first bit line BL11, a first layer second bit line BL12, a first layer third bit line BL13, and a first layer fourth bit line BL14. Although only four bit lines are illustrated in FIG. 8B for convenience, a larger number of bit lines may also be provided on the substrate 201. The first layer first bit line BL11, the first layer second bit line BL12, the first layer third bit line BL13, and the first layer fourth bit line BL14 extend in the second direction and may be spaced apart from each other in the third direction (Y direction).

Referring to FIG. 8D, a first insulating layer 202 may be formed at a uniform height on the substrate 201 to cover the first layer bit line BL1. FIG. 8E is a cross-sectional view in the same direction as FIG. 8C. Referring to FIG. 8E, the first insulating layer 202 may be provided to cover a sidewall and an upper surface of the first layer first bit line BL11, a sidewall and an upper surface of the first layer second bit line BL12, and an upper surface of the substrate 201 between the first layer first bit line BL11 and the second bit line BL12. Although not shown, the first insulating layer 202 may cover sidewalls and upper surfaces of the first layer third bit line BL13 and the first layer fourth bit line BL14.

Referring to FIG. 8F, a plurality of first source/drain contacts 104 which penetrate the first insulating layer 202 and electrically contact the first layer bit line BL1 may be formed. For example, the first insulating layer 202 may be partially etched to form a plurality of holes through the first insulating layer 202 so that a portion of the upper surface of the first layer bit line BL1 is exposed, and then a plurality of first source/drain contacts 104 may be formed by filling a conductive material or a doped semiconductor material in the plurality of holes.

FIG. 8G is a plan view after forming the plurality of first source/drain contacts 104, and FIG. 8H is a cross-sectional view taken along line A2-A2′ shown in FIG. 8G. Referring to FIGS. 8G and 8H, the plurality of first source/drain contacts 104 may be spaced apart from each other and arranged in two dimensions. Each of the plurality of first source/drain contacts 104 may be in electrical contact with a corresponding one of the first layer first bit line BL11, the first layer second bit line BL12, the first layer third bit line BL13, and the first layer fourth bit line BL14.

Referring to FIG. 8I, a second insulating layer 203 may be formed to have a uniform height to cover the upper surface of the first insulating layer 202 and the upper surfaces of the plurality of first source/drain contacts 104.

Referring to FIG. 8J, a plurality of holes 204 penetrating the second insulating layer 203 may be formed to expose the plurality of first source/drain contacts 104 by partially etching the second insulating layer 203. The size of each of the plurality of holes 204 may be larger than the size of each of the plurality of first source/drain contacts 104 such that most regions of the plurality of first source/drain contacts 104 are exposed.

FIG. 8K is a plan view after forming the plurality of holes 204. Referring to FIG. 8K, a width of each of a plurality of holes 204 in the second direction may be greater than a width of each of a plurality of first source/drain contacts 104 in the second direction. Therefore, the upper surface of the first insulating layer 202 on both sides of the first source/drain contact 104 in the second direction may be exposed through the plurality of holes 204.

Referring to FIG. 8L, a channel layer 103, which is in electrical contact with the first source/drain contact 104, a ferroelectric layer 102 in the channel layer 103, and a gate electrode 101 in the ferroelectric layer 102 may be sequentially formed inside each of the plurality of holes 204. For example, after forming the channel layer 103 at a constant thickness along the upper surface of the second insulating layer 203, the inner wall of each of the plurality of holes 204, and the bottom of each of the plurality of holes 204, the ferroelectric layer 102 may be formed at a constant thickness on the surface of the channel layer 103, and finally, the gate electrode 101 may be formed at a constant thickness on the surface of the ferroelectric layer 102.

Referring to FIG. 8M, the material of the channel layer 103, the material of the ferroelectric layer 102, and the material of the gate electrode 101 provided inside each of the plurality of holes 204 may be left, and the material of the channel layer 103, the material of the ferroelectric layer 102, and the material of the gate electrode 101 on the upper surface of the second insulating layer 203 may be removed. For example, a planarization process may be performed so that the upper surface of the second insulating layer 203 is exposed through a chemical mechanical polishing (CMP) method.

FIG. 8N is a plan view after performing the planarization process illustrated in FIG. 8M. Referring to FIG. 8N, a gate electrode 101, a ferroelectric layer 102, and a channel layer 103 may be provided to fill each of the plurality of holes 204. The gate electrode 101, the ferroelectric layer 102, and the channel layer 103 may be arranged concentrically in each of the plurality of holes 204.

Referring to FIG. 8O, a third insulating layer 205 may be formed to have a constant thickness to cover upper surfaces of the second insulating layer 203, the gate electrode 101, the ferroelectric layer 102, and the channel layer 103. In addition, a plurality of holes penetrating the third insulating layer 205 may be formed so that at least a portion of the upper surface of the gate electrode 101 is exposed. Then, a plurality of gate contacts 106 may be formed by filling a conductive material in the plurality of holes penetrating the third insulating layer 205. Then, a gate contact 106 which penetrates the third insulating layer 205 and electrically contacts the gate electrode 101 may be formed.

FIG. 8P is a plan view after performing a process of forming the gate contact 106 shown in FIG. 8O, and FIG. 8Q is a cross-sectional view taken along line A3-A3′ shown in FIG. 8P. Referring to FIGS. 8P and 8Q, the plurality of gate contacts 106 may be spaced apart from each other and arranged in two dimensions. In particular, the plurality of gate contacts 106 may be arranged at regular intervals in an inclined direction between the second direction and the third direction. Each of the plurality of gate contacts 106 may be in electrical contact with a corresponding one of the plurality of gate electrodes 101.

Referring to FIG. 8R, a plurality of word lines may be formed on the third insulation layer 205 to be in electrical contact with the plurality of gate contacts 106. Although only the first layer first word line WL11 and the first layer second word line WL12 are illustrated in FIG. 8R, a larger number of word lines may be formed.

FIG. 8S is a plan view after performing a process of forming the plurality of word lines shown in FIG. 8R, and FIG. 8T is a cross-sectional view taken along line A4-A4′ shown in FIG. 8S. Referring to FIGS. 8S and 8T, the plurality of word lines extending in an inclined direction between the second direction and the third direction and arranged parallel to each other, for example, a first word line WL11, a first layer second word line WL12, and a first layer third word line WL13 may be formed. Each of the first word line WL11, the first layer second word line WL12, and the first layer third word line WL13 may be electrically connected to the plurality of gate contacts 106 arranged in an inclined direction between the second direction and the third direction.

Referring to FIG. 8U, the fourth insulating layer 206 may be formed to have a predetermined thickness to completely cover the third insulating layer 205 and the plurality of word lines, for example, the first layer first word line WL11, the first layer second word line WL12, and the like. In addition, a plurality of holes penetrating the fourth insulating layer 206 and the third insulating layer 205 may be formed so that at least a portion of the upper surface of the channel layer 103 is exposed. Then, a plurality of second source/drain contacts 105 may be formed by filling a conductive material or a doped semiconductor material in the plurality of holes penetrating the fourth insulating layer 206 and the third insulating layer 205. Each of the plurality of second source/drain contacts 105 may be in electrical contact with a corresponding one of the plurality of channel layers 103.

Referring to FIG. 8V, a second layer bit line BL2 may be formed on the fourth insulating layer 206. For example, after depositing a conductive metal layer on the upper surface of the fourth insulating layer 206, the conductive metal layer may be patterned to form the second layer bit line BL2. Like the first layer bit line BL1 described with reference to FIGS. 8B and 8C, the second layer bit line BL2 may include a plurality of bit lines extending in the second direction and spaced apart from each other and arranged parallel to each other. Each of the plurality of bit lines may be in electrical contact with the plurality of second source/drain contacts 105 arranged in the second direction.

Thereafter, the processes described with reference to FIGS. 8D to 8U may be performed again. Unit memory cells may be stacked in a plurality of layers by repeating the processes shown in FIGS. 8A to 8V described above. Therefore, since the unit memory cells may be relatively easily stacked into a plurality of layers, the degree of integration of the semiconductor device 200 may be further increased.

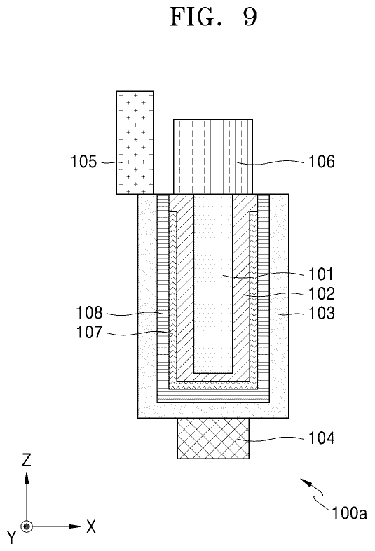

FIG. 9 is a vertical cross-sectional view schematically showing a structure of a ferroelectric field effect transistor 100a according to at least one embodiment. Referring to FIG. 9, a ferroelectric field effect transistor 100a includes all the configurations of the ferroelectric field effect transistor 100 shown in FIG. 1, and may further include an intermediate electrode 107 and an interlayer insulating layer 108. The intermediate electrode 107 may be provided between the ferroelectric layer 102 and the channel layer 103. The intermediate electrode 107 may extend in the first direction while surrounding a portion of a side surface and a lower surface of the ferroelectric layer 102. In addition, the interlayer insulating layer 108 may be provided between the intermediate electrode 107 and the channel layer 103. The interlayer insulating layer 108 may extend in the first direction while surrounding a side surface and a lower surface of the intermediate electrode 107.

The intermediate electrode 107 may include a conductive material, such as a conductive metal, a conductive metal oxide, a conductive metal nitride, etc. The interlayer insulating layer 108 may include a low dielectric constant insulating material such as SiO₂, SiN, or the like. The intermediate electrode 107 may be provided not to be in electrical contact with the gate contact 106. For example, the upper surface of the intermediate electrode 107 may be covered with the ferroelectric layer 102 or the interlayer insulating layer 108, and the intermediate electrode 107 and the gate contact 106 may be sufficiently spaced apart from each other. In this respect, the intermediate electrode 107 may serve as a floating gate.

According to at least one embodiment, data retention may be improved through the floating gate. Furthermore, since the interlayer insulating layer 108 is placed outside the ferroelectric layer 102, the electric flux density applied to the interlayer insulating layer 108 may be relatively low and the electric flux density applied to the ferroelectric layer 102 may be relatively high. Therefore, the operating performance and reliability of the ferroelectric field effect transistor 100a may be improved compared to a structure in which the channel layer is located at the center and the gate electrode is arranged at the outermost side.

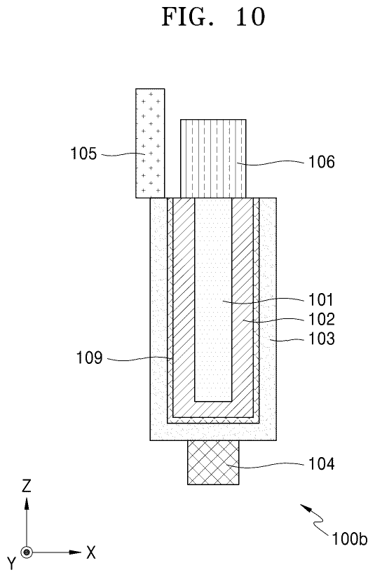

FIG. 10 is a vertical cross-sectional view schematically showing a structure of a ferroelectric field effect transistor according to at least one embodiment. Referring to FIG. 10, a ferroelectric field effect transistor 100b includes all the configurations of the ferroelectric field effect transistor 100 shown in FIG. 1, and may further include an oxygen-deficient layer 109. The oxygen-deficient layer 109 is provided between the ferroelectric layer 102 and the channel layer 103, surrounds a side surface and a lower surface of the ferroelectric layer 102, and may extend in the first direction.

In the ferroelectric field effect transistor 100b illustrated in FIG. 10, the channel layer 103 may include an oxide semiconductor material. When the channel layer 103 includes an oxide semiconductor, the ferroelectric field effect transistor 100b has a relatively low leakage current characteristic in an off state and may have a relatively fast operation speed due to the high electron mobility of the oxide semiconductor material.

Meanwhile, within the channel layer 103 containing an oxide semiconductor material, there may be almost no minority carriers due to the high bandgap of the oxide semiconductor material. For example, there may be almost no holes in the channel layer 103. For this reason, when the channel layer 103 and the ferroelectric layer 102 are in direct contact with each other, the ferroelectric layer 102 may have polarization in only one direction. For example, even if a voltage higher than or equal to a coercive voltage is applied to the gate electrode 101 of the ferroelectric field effect transistor 100b, polarization switching hardly occurs in the ferroelectric layer 102, and only the intensity of polarization may change. Therefore, when the channel layer 103 and the ferroelectric layer 102 come into direct contact with each other, the memory window, which is a difference between two different threshold voltages of the ferroelectric field effect transistor 100b, may be reduced.

The oxygen-deficient layer 109 may be provided between the ferroelectric layer 102 and the channel layer 103 to enable and/or facilitate polarization switching of the ferroelectric layer 102. Like the channel layer 103, the oxygen-deficient layer 109 includes an oxide semiconductor material and may have a higher concentration of oxygen vacancies than the channel layer 103. The oxygen-deficient layer 109 having a relatively high concentration of oxygen vacancies may increase the amount of depletion charge having a positive charge value in a depletion region. Therefore, the ferroelectric layer 102 is in direct contact with the oxygen-deficient layer 109 between the ferroelectric layer 102 and the channel layer 103, or the ferroelectric layer 102 is positioned closer to the oxygen-deficient layer 109 than the channel layer 103, and thus, the ferroelectric layer 102 may be capable of polarization switching in both directions. As a result, the memory window of the ferroelectric field effect transistor 100b may be increased.

The oxygen-deficient layer 109 may include an oxide semiconductor material including an oxide of at least one metal from among indium (In), gallium (Ga), zinc (Zn), tungsten (W), and tin (Sn), for example. The oxygen-deficient layer 109 and the channel layer 103 may include the same oxide semiconductor material, and/or may include different oxide semiconductor materials. For example, both the channel layer 103 and the oxygen-deficient layer 109 may include IGZO, or the channel layer 103 may include IGZO and the oxygen-deficient layer 109 may include IZO.

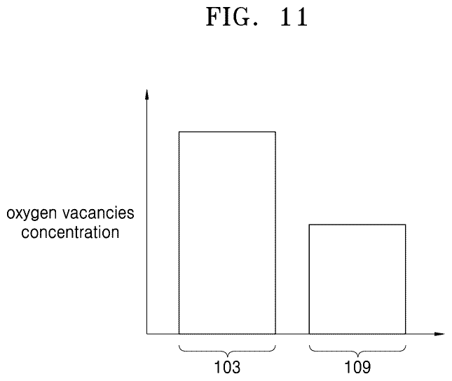

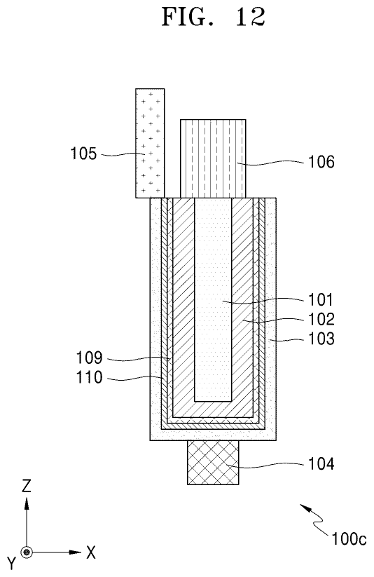

FIG. 11 is a graph showing the concentration distribution of oxygen vacancies in the oxygen-deficient layer 109 and the channel layer 103 of the ferroelectric field effect transistor 100b shown in FIG. 10. Referring to FIG. 11, a concentration of oxygen vacancies in the oxygen-deficient layer 109 may be higher than a concentration of oxygen vacancies in the channel layer 103. For example, the concentration of oxygen vacancies in the oxygen-deficient layer 109 may be about 1.2 times or more, about 1.5 times or more, and/or about twice or more as high as the concentration of oxygen vacancies in the channel layer 103. The concentration of oxygen vacancies may be measured, for example, using secondary ion mass spectrometry (SIMS) or X-ray photoelectron spectroscopy (XPS).

Oxygen vacancies in the oxygen-deficient layer 109 may be formed by deficiently supplying an oxygen material in the process of forming the oxygen-deficient layer 109. For example, the oxygen-deficient layer 109 may be formed by a sputtering, atomic layer deposition (ALD), or chemical vapor deposition (CVD) method. In the process of depositing the oxide semiconductor material of the oxygen-deficient layer 109, oxygen vacancies may be formed in the oxygen-deficient layer 109 by supplying oxygen into the chamber in a stoichiometrically deficient manner, and the concentration of the oxygen vacancies may be adjusted according to the amount of oxygen provided in the chamber. Therefore, the oxide semiconductor material of the oxygen-deficient layer 109 may have a stoichiometrically oxygen-deficient composition.

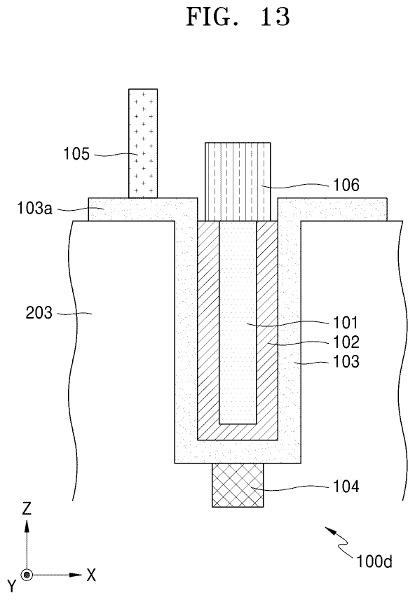

FIG. 12 is a vertical cross-sectional view schematically showing a structure of a ferroelectric field effect transistor according to another embodiment. Referring to FIG. 12, a ferroelectric field effect transistor 100c includes all the configurations of the ferroelectric field effect transistor 100c shown in FIG. 10, and may further include a diffusion barrier layer 110. The diffusion barrier layer 110 is provided between the oxygen-deficient layer 109 and the channel layer 103, surrounds a side surface and a lower surface of the oxygen-deficient layer 109, and may extend in the first direction.

When the channel layer 103 and the oxygen-deficient layer 109 are in direct contact with each other, the channel layer 103 may deteriorate due to oxygen exchange between the channel layer 103 and the oxygen-deficient layer 109. For example, if the ferroelectric field effect transistor 100b shown in FIG. 10 repeats the write operation, the oxygen-deficient layer 109 expands as the concentration of oxygen vacancies in the channel layer 103 gradually increases, which may lead to an increase in leakage current while the ferroelectric field effect transistor 100b is turned off. A diffusion barrier layer 110 may be provided between the channel layer 103 and the oxygen-deficient layer 109 to minimize or prevent deterioration of the channel layer 103 by reducing or preventing oxygen exchange between the channel layer 103 and the oxygen-deficient layer 109. The diffusion barrier layer 110 may include a nitride material as a material for reducing or preventing oxygen exchange between the channel layer 103 and the oxygen-deficient layer 109. For example, the diffusion barrier layer 110 may include at least one of silicon nitride (SiN), hafnium nitride (HfN), and aluminum nitride (AlN).

FIG. 13 is a vertical cross-sectional view schematically showing a structure of a ferroelectric field effect transistor according to another embodiment. Referring to FIG. 13, a channel layer 103 of a ferroelectric field effect transistor 100d may include a channel extension portion 103a extending over an upper surface of a second insulating layer 203. The channel extension portion 103a may extend from the channel layer 103 to the outside of the channel layer 103 on a plane (e.g., a horizontal plane) in the second direction (X direction) and the third direction (Y direction). For example, the channel extension portion 103a may be formed by leaving a portion of the material of the channel layer 103 without removing the portion of the material of the channel layer 103 on the upper surface of the second insulating layer 203 in the process illustrated in FIGS. 8L and 8M. Accordingly, the channel extension portion 103a may include the same material as the channel layer 103. The second source/drain contact 105 may be provided to be in electrical contact with the channel 103 via the channel extension portion 103a. Then, a contact area between the second source/drain contact 105 and the channel layer 103 may increase.

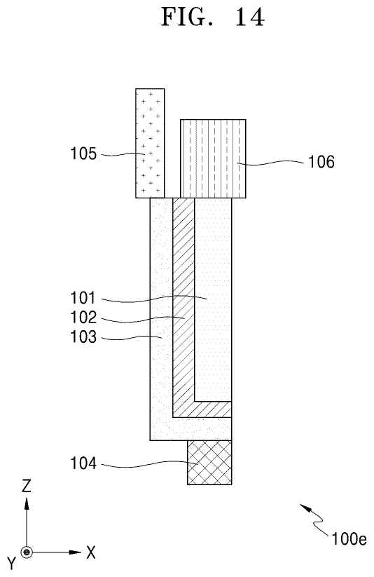

FIG. 14 is a vertical cross-sectional view schematically showing a structure of a ferroelectric field effect transistor according to another embodiment. In the ferroelectric field effect transistors described above, it was explained that the cylindrical gate electrode 101 was arranged at the center and the ferroelectric layer 102 and the channel layer 103 were sequentially arranged in a concentric shape to surround the cylindrical gate electrode 101. However, according to another embodiment, instead of a concentric structure, a ferroelectric field effect transistor may have a structure in which the ferroelectric layer 102 and the channel layer 103 are arranged only on one side surface of the gate electrode 101. For example, referring to FIG. 14, the ferroelectric layer 102 of the ferroelectric field effect transistor 100e may extend in the first direction on the first side surface of the gate electrode 101. In addition, the channel layer 103 of the ferroelectric field effect transistor 100e may extend in the first direction on the first side surface of the ferroelectric layer 102. The ferroelectric layer 102 may be provided to cover the first side surface and the lower surface of the gate electrode 101, or may be provided to cover only the first side surface of the gate electrode 101. The channel layer 103 may be provided to cover the first side surface and the lower surface of the ferroelectric layer 102, or may be provided to cover only the first side surface of the ferroelectric layer 102. Therefore, the second side surface of the gate electrode 101 opposite to the first side surface may be exposed without being covered by the ferroelectric layer 102 and the channel layer 103. According to at least one embodiment, the lower surface of the gate electrode 101 may also be exposed without being covered by the ferroelectric layer 102 and the channel layer 103.

The ferroelectric field effect transistor having a vertical structure, the semiconductor device including the ferroelectric field effect transistor, the method of fabricating the semiconductor device, and the method of operating the semiconductor device have been described with reference to the embodiments illustrated in the drawings.

However, it should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first layer bit line;
a second layer bit line spaced apart from the first layer bit line in a first direction;
a third layer bit line spaced apart from the second layer bit line in the first direction; and
a plurality of ferroelectric field effect transistors including one or more ferroelectric field effect transistors between the first layer bit line and the second layer bit line and one or more ferroelectric field effect transistors between the second layer bit line and the third layer bit line,
wherein each of the plurality of ferroelectric field effect transistors comprises
a gate electrode extending in the first direction,
a ferroelectric layer extending in the first direction on a side surface of the gate electrode,
a channel layer extending in the first direction on a side surface of the ferroelectric layer,
a first source/drain contact electrically connected to a lower surface of the channel layer,
a second source/drain contact electrically connected to an upper surface of the channel layer, and
a gate contact electrically connected to an upper surface of the gate electrode, and
wherein the first source/drain contact of each of the one or more ferroelectric field effect transistors between the first layer bit line and the second layer bit line is electrically connected to the first layer bit line, and the second source/drain contact of each of the one or more ferroelectric field effect transistors between the first layer bit line and the second layer bit line is electrically connected to the second layer bit line.

2. The semiconductor device of claim 1, wherein
the first source/drain contact of each of the one or more ferroelectric field effect transistors between the second layer bit line and the third layer bit line is electrically connected to the second layer bit line, and
the second source/drain contact of each of the one or more ferroelectric field effect transistors between the second layer bit line and the third layer bit line is electrically connected to the third layer bit line.

3. The semiconductor device of claim 2, wherein the second layer bit line is configured as a common bit line between the one or more ferroelectric field effect transistors between the first layer bit line and the second layer bit line and the one or more ferroelectric field effect transistors provided between the second layer bit line and the third layer bit line.

4. The semiconductor device of claim 3, further comprising:
a first layer word line spaced apart from the first layer bit line and the second layer bit line in the first direction such that the first layer word line is between the first layer bit line and the second layer bit line; and
a second layer word line spaced apart from the second layer bit line and the third layer bit line in the first direction such that the second layer word line is between the second layer bit line and the third layer bit line,
wherein the gate contact of each of the one or more ferroelectric field effect transistors between the first layer bit line and the second layer bit line is electrically connected to the first layer word line, and
the gate contact of each of the one or more ferroelectric field effect transistors between the second layer bit line and the third layer bit line is electrically connected to the second layer word line.

5. The semiconductor device of claim 4, wherein
each of the first layer bit line, the second layer bit line, and the third layer bit line comprises a plurality of bit lines extending in a second direction perpendicular to the first direction and spaced apart from each other in a third direction perpendicular to the first direction and the second direction, and
each of the first layer word line and the second layer word line comprises a plurality of word lines crossing the plurality of bit lines in a plan view.

6. The semiconductor device of claim 5, wherein
the plurality of ferroelectric field effect transistors are arranged in a hexagonal lattice form, and
the plurality of word lines obliquely cross the plurality of bit lines in the plan view.

7. The semiconductor device of claim 5, further comprising:
a first row decoder configured to provide a control signal to the plurality of word lines of the first layer word line;
a second row decoder configured to provide a control signal to the plurality of word lines of the second layer word line;
a first column decoder electrically connected to the plurality of bit lines of the first layer bit line;
a second column decoder electrically connected to the plurality of bit lines of the second layer bit line;
a third column decoder electrically connected to the plurality of bit lines of the third layer bit line; and
a sense amplifier electrically connected to the second column decoder and configured to amplify a signal output from the second column decoder.

8. The semiconductor device of claim 7, wherein the semiconductor device is configured such that
when the one or more ferroelectric field effect transistors between the first layer bit line and the second layer bit line are turned on, a driving voltage is applied to the first layer bit line, and a current flows from the first layer bit line to the second layer bit line, and
when the one or more ferroelectric field effect transistors between the second layer bit line and the third layer bit line are turned on, a driving voltage is applied to the third layer bit line, and a current flows from the third layer bit line to the second layer bit line.

9. The semiconductor device of claim 7, wherein
the semiconductor device comprises a plurality of bit line layers, and the sense amplifier is included in a plurality of sense amplifiers, and
wherein each of the plurality of sense amplifiers are only on bit lines of even-numbered bit line layers.

10. An operating method of a semiconductor device including a plurality of first layer ferroelectric field effect transistors including at least one of ferroelectric field effect transistor between a first layer bit line and a second layer bit line; and a plurality of second layer ferroelectric field effect transistors between the second layer bit line and a third layer bit line, the operating method comprising:
applying a read voltage to a gate electrode of each of the plurality of first layer ferroelectric field effect transistors;
applying a driving voltage to the first layer bit line such that a signal is output from the first layer bit line through the second layer bit line;
applying a read voltage to a gate electrode of each of the plurality of second layer ferroelectric field effect transistors; and
applying a driving voltage to the third layer bit line such that a signal is output from the third layer bit line through the second layer bit line.

11. The method of claim 10, further comprising:
amplifying the signal output from the second layer bit line.

12. The method of claim 10, wherein
each of the first layer bit line, the second layer bit line, and the third layer bit line comprises a plurality of bit lines,
the outputting of the signal from the first layer bit line through the second layer bit line comprises sequentially outputting a signal through the plurality of bit lines of the first layer bit line and the plurality of bit lines of the second layer bit line, and
the outputting of the signal from the third layer bit line through the second layer bit line comprises sequentially outputting a signal through the plurality of bit lines of the third layer bit line and the plurality of bit lines of the second layer bit line.

13. A ferroelectric field effect transistor comprising:
a gate electrode extending in a first direction;
a ferroelectric layer extending in the first direction on a side surface of the gate electrode;
a channel layer extending in the first direction on a side surface of the ferroelectric layer;
a first source/drain contact electrically connected to a lower surface of the channel layer;
a second source/drain contact electrically connected to an upper surface of the channel layer; and
a gate contact electrically connected to an upper surface of the gate electrode.

14. The ferroelectric field effect transistor of claim 13, wherein, in a plan view,
the second source/drain contact overlaps with a portion of the upper surface of the channel layer and is spaced apart from the gate electrode such that the second source/drain contact is not in electrical contact with the gate electrode, and
the gate contact overlaps with at least a portion of the upper surface of the gate electrode and is spaced apart from the channel layer such that the gate contact is not in electrical contact with the channel layer.

15. The ferroelectric field effect transistor of claim 14, wherein
a portion of the second source/drain contact protrudes outward from the channel layer on a plane in a second direction perpendicular to the first direction and in a third direction perpendicular to the first direction and the second direction, and
a portion of the gate contact protrudes outward from the gate electrode on a plane in the second direction perpendicular to the first direction and in the third direction perpendicular to the first direction and the second direction, to contact a portion of an upper surface of the ferroelectric layer.

16. The ferroelectric field effect transistor of claim 14, wherein, in a plan view, a portion of the gate electrode between the second source/drain contact and the gate contact is exposed without being covered by the gate contact.

17. The ferroelectric field effect transistor of claim 13, wherein
the channel layer, the first source/drain contact, and the second source/drain contact each comprise one semiconductor material among a group IV semiconductor, a group III-V compound semiconductor, or a group II-VI compound semiconductor,
the channel layer is doped with a first conductivity type, and
the first source/drain contact and the second source/drain contact are doped with a second conductivity type electrically different to the first conductivity type.

18. The ferroelectric field effect transistor of claim 13, wherein the channel layer comprises an oxide semiconductor material, and
the first source/drain contact and the second source/drain contact each comprise at least one of a conductive metal, a conductive metal oxide, or a conductive metal nitride.

19. The ferroelectric field effect transistor of claim 18, further comprising:
an oxygen-deficient layer between the ferroelectric layer and the channel layer, the oxygen-deficient layer surrounding the side surface and a lower surface of the ferroelectric layer; and
a diffusion barrier layer between the oxygen-deficient layer and the channel layer, the diffusion barrier layer surrounding a side surface and a lower surface of the oxygen-deficient layer,
wherein the oxygen-deficient layer comprises an oxide semiconductor material,
a concentration of oxygen vacancies in the oxygen-deficient layer is greater than a concentration of oxygen vacancies in the channel layer, and
the diffusion barrier layer comprises at least one of silicon nitride (SiN), hafnium nitride (HfN), or aluminum nitride (AlN).

20. The ferroelectric field effect transistor of claim 13, further comprising:
an intermediate electrode between the ferroelectric layer and the channel layer, the intermediate electrode surrounding at least a portion of the side surface and a lower surface of the ferroelectric layer; and
an interlayer insulating layer surrounding a side surface and a lower surface of the intermediate electrode such that the interlayer insulating layer electrically insulates the intermediate electrode from the channel layer,
wherein an upper surface of the intermediate electrode is covered by at least one of the ferroelectric layer or the interlayer insulating layer such that the intermediate electrode is not in electrical contact with the gate contact.
